(19) United States
(12) Patent Application Publication
(10) Pub. No.: US 2006/0030093 A1
(43) Pub. Date: Feb. 9, 2006

(54) Strained semiconductor devices and method for forming at least a portion thereof

(76) Inventors: Da Zhang, Austin, TX (US); Brian J. Goolsby, Austin, TX (US); Eric D. Luckowski, Round Rock, TX (US); Bich-Yen Nguyen, Austin, TX (US); Mariam G. Sadaka, Austin, TX (US); Voon-Yew Thean, Austin, TX (US); Ted R. White, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/913,099

(22) Filed: Aug. 6, 2004

(51) Int. Cl. H01L 21/8234

(52) U.S. Cl. 438/197

(57) ABSTRACT

A method for forming at least a portion of a semiconductor device includes providing a substrate and epitaxially forming an etch stop layer over the substrate. A first layer is provided over the etch stop layer, wherein the first layer is selectively etchable with regard to the etch stop layer. A structure is provided over a region of the first layer, wherein the region is not all of the first layer. In addition, the method includes etching at least a portion of the first layer that is outside of the region, wherein the etch stop layer is used an as etch stop. A strained layer is epitaxially grown in the etch-recessed region.

### BACKGROUND

The present disclosure relates generally to semiconductor devices, and more particularly, to strained semiconductor devices and method for forming at least a portion thereof.

Strained channel is promising for promoting MOSFET transistor performance by enhancing carrier mobility. Specifically, PMOS prefers compressive strain and NMOS prefers tensile strain. In a conventional planar process for making strained transistors, a strained layer is formed as the transistor channel prior to transistor gate dielectric formation. The property of the strained channel is however degraded by subsequent processed. For example, the high temperature gate oxidation process induces species diffusion and strain relaxation. In addition, for a strained material different from Si, a Si cap on the top is typically required due to the general incompatibility of the strained layer and a gate dielectric. This Si cap layer degrades the efficiency of the strained layer as the carrier conducting channel.

To avoid the drawbacks of the conventional planar process, an approach with etch-and-refill from the transistor source/drain (S/D) region has been proposed in prior methods. However, there are many issues associated with the corresponding etch without any specific control. Due to etch rate non-uniformity (e.g., micro loading effect), S/D recessing depths are different on different areas of the wafer, and this impacts device integration. In the case with an isotropic etch for complete lateral removal of the channel, a faceted surface is eventually formed to impact the next step epitaxial film growth. As etch rate in the vertical direction is generally larger than that in the lateral direction, the process can not de-couple the control of the etch depths in vertical and lateral directions.

To avoid the use of Si capping, an etch-and-refill approach has been proposed in prior methods. However, the corresponding etch is isotropic and thus complete lateral removal of the channel leads to deep vertical etching. As a result, this makes the re-filled SiGe layer much thicker than a critical thickness, and therefore the strain in SiGe is hard to guarantee.

Accordingly, it would be desirable to provide an improved strained semiconductor device manufacturing method for overcoming the problems in the art.

### SUMMARY

According to one embodiment, a method for forming at least a portion of a semiconductor device includes providing a substrate and epitaxially forming an etch stop layer over the substrate. A first layer is provided over the etch stop layer, wherein the first layer is selectively etchable with regard to the etch stop layer. A structure is provided over a region of the first layer, wherein the region is not all of the first layer. In addition, the method includes etching at least a portion of the first layer that is outside of the region, wherein the etch stop layer is used an as etch stop. A strained layer is epitaxially grown in the etch-recessed region.

### BRIEF DESCRIPTION OF THE DRAWINGS

The embodiments of the present disclosure are illustrated by way of example and not limited by the accompanying figures, in which like references indicate similar elements, and in which:

FIGS. 1-5 show a series of partial cross-sectional views of a stressed semiconductor device at various stages during manufacture of an integrated circuit according to an embodiment of the present disclosure;

FIG. 6 is a cross-sectional drawing view of an exemplary transistor fabricated according to an embodiment of the present disclosure;

FIGS. 7-8 show a series of partial cross-sectional views of a stressed semiconductor device at various stages during manufacture of an integrated circuit according to another embodiment of the present disclosure; and

FIG. 9 is a cross-sectional drawing view of an exemplary transistor fabricated according to another embodiment of the present disclosure.

The use of the same reference symbols in different drawings indicates similar or identical items. Skilled artisans will also appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

The embodiments of the present disclosure provide a novel approach for the formation of a strained channel of a semiconductor device, for example, a transistor. In one embodiment, the method includes, but is not limited to, the following: start with a semiconductor substrate, such as an SOI or bulk Si substrate; epitaxially grow a thin Si_{1-y}Ge_{y} layer, for example, approximately 50 A; epitaxially grow a thin Si layer on top of the Si_{1-y}Ge_{y}, for example, approximately 300 A; use conventional processes for isolation (e.g., shallow trench isolation) and gate structure formation until after forming a gate sidewall spacer; selectively etch the channel Si, wherein the Si etching is highly selective to SiGe and therefore the process removes Si in the lateral direction (including in the channel and S/D regions); refill the recessed area with Si₁₋ₓGeₓ to induce channel strain, and thereafter use conventional processes for completing the device formation. Additional embodiments are further described herein below.

The present embodiments overcome problems in the art, for example, in at least one or more of the following ways. Application of the thin Si_{1-y}Ge_{y} layer provides an etch stop for Si removal, while in the mean time, the thin Si_{1-y}Ge_{y} layer preserves the crystal structure of the underlying substrate Si. The final Si removal is lateral, wherein the lateral removal enables complete channel etching at a controlled thickness. Accordingly, the refilled Si₁₋ₓGeₓ is therefore strained. Furthermore, dopants can be incorporated in the final refilling step to enable the direct formation of S/D extension without implantation.

Additionally, advantages provided by the embodiments of the present disclosure include, but are not limited to, enhanced carrier mobility induced by the strained Si₁₋ₓGeₓ; and improved control of channel strain, wherein a final channel layer thickness is well controlled and channel layer deposition occurs after major thermal steps have been completed (e.g., STI formation, gate dielectric formation, gate spacer densification, etc.).

Referring now to the drawings, FIGS. 1-5 show a series of partial cross-sectional views of a stressed semiconductor device at various stages during manufacture of an integrated circuit (including a portion of a semiconductor device), according to an embodiment of the present disclosure. In FIG. 1, semiconductor device 10 includes a semiconductor substrate 12, a crystalline etch stop layer 14 overlying substrate 12, and a semiconductor layer 16 overlying etch stop layer 14, wherein layer 16 comprises a material that is selectively etchable with respect to etch stop layer 14.

Semiconductor substrate 12 can include, for example, a bulk semiconductor substrate, a semiconductor-on-insulator substrate, or other suitable substrate. In one embodiment, substrate 12 includes a silicon-on-insulator (SOI) substrate. In another embodiment, substrate 12 includes a bulk silicon substrate. In addition, crystalline etch stop layer 14 can have a thickness on the order of 50-300 angstroms. In one embodiment, crystalline etch stop layer 14 includes an epitaxially grown silicon germanium (SiGe) layer having a thickness of approximately 150 angstroms. In another embodiment, etch stop layer 14 includes one or more of Si_{1-y-z}Ge_{y}C_{z} or Si_{1-z}C_{z}. Furthermore, semiconductor layer 16 has a thickness on the order of 200-1000 angstroms. In one embodiment, layer 16 includes a silicon layer having a thickness of approximately 300 angstroms.

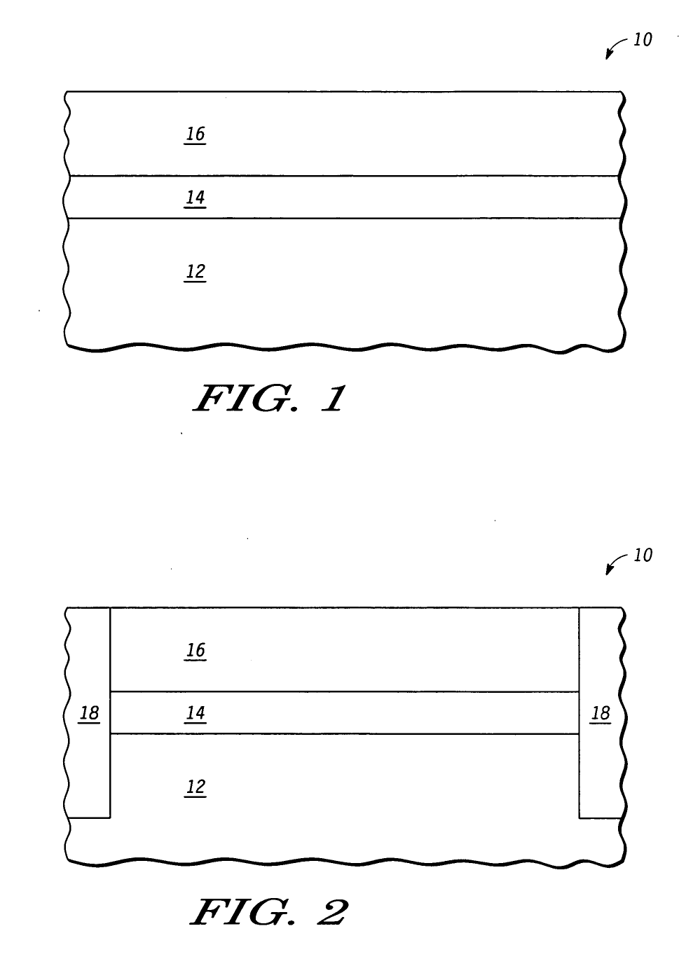

In FIG. 2, shallow trench isolation regions 18 are formed, using conventional techniques known in the art. In an embodiment wherein the semiconductor substrate 12 includes a semiconductor-on-insulator substrate, the shallow trench isolation regions 18 extend from a top of the semiconductor-on-insulator substrate down to a buried oxide layer of the semiconductor-on-insulator substrate.

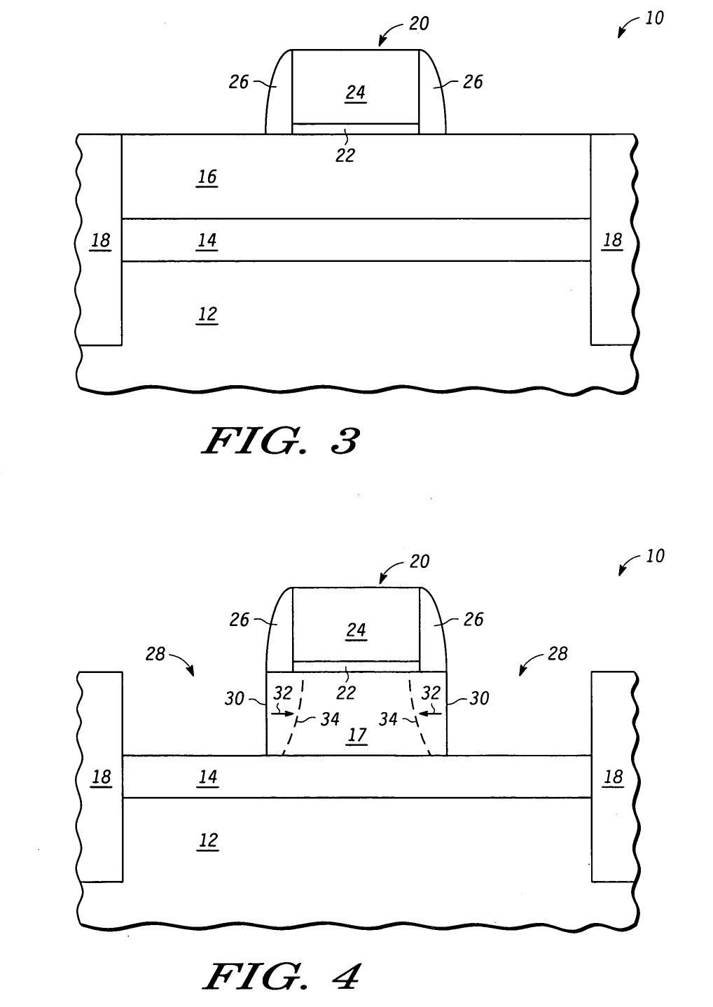

In FIG. 3, a gate structure 20 is formed using conventional techniques. In one embodiment, gate structure 20 includes a gate dielectric 22, gate electrode 24, and sidewall spacers 26. Gate structure 20 overlies a region of the semiconductor layer 16, wherein the region is not all of semiconductor layer 16. In addition, gate dielectric 22, gate electrode 24, and sidewall spacers 26 include a dielectric, electrode, and sidewall spacers, respectively, as appropriate for the requirements of a desired semiconductor device application. For example, in one embodiment, gate dielectric 22 includes an oxide having a thickness on the order of between 10 and 50 angstroms. Gate electrode 24 can include a polysilicon or metal electrode having a thickness on the order of between 300 to 1500 angstroms. Furthermore, sidewall spacers 26 can include nitride spacers, and may further include, composite sidewall spacers having a liner and one or more materials to form the spacers.

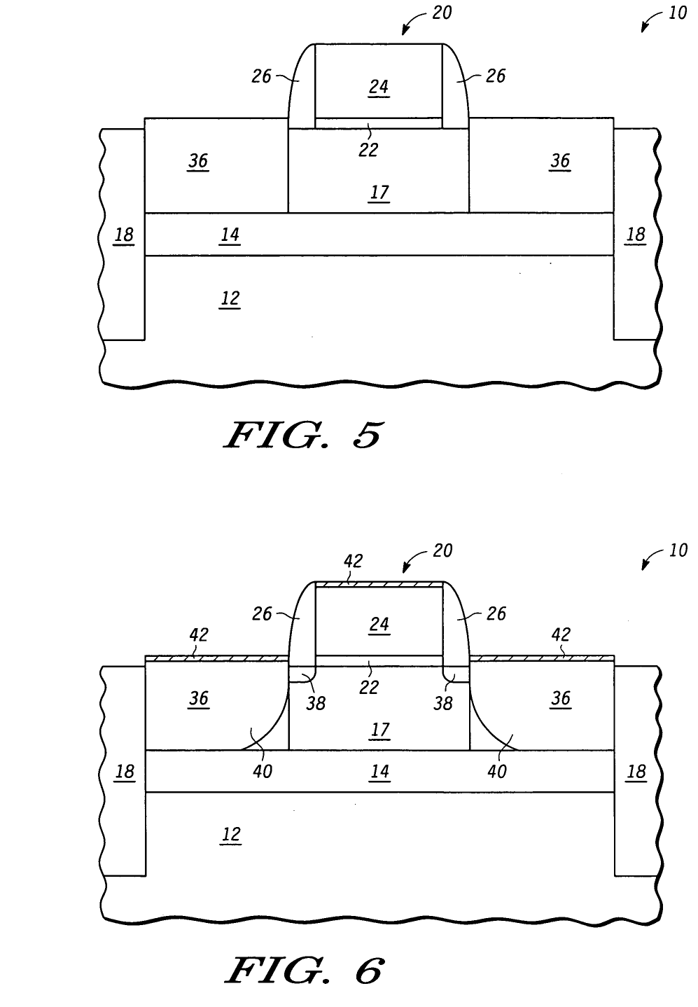

Referring now to FIG. 4, following formation of the gate structure 20, semiconductor device 10 is subjected to an etch process. In one embodiment, the etch process includes an anisotropic etch. The anisotropic etch removes a portion of the semiconductor layer 16 not covered by gate structure 20, thereby forming recess openings 28. In other words, the etch process includes etching a portion of the semiconductor layer 16 that is outside the region (discussed herein above) and wherein the etch stop layer is used as an etch stop. The recess openings 28 are bounded by the shallow trench isolation regions 18 and also bounded by the etch stop layer 14 underlying semiconductor layer 16. Forming the recess openings 28 also forms vertical edges 30 of a remaining portion of semiconductor layer 16 (FIG. 3), the remaining portion being indicated by reference numeral 17 (FIG. 4). In one embodiment, the remaining portion 17 becomes a channel region of semiconductor device 10. In addition, after etching, the top surface of the etch stop layer comprises a substantially planar surface. The embodiments of the present disclosure provide for flexible lateral etch control.

In FIG. 5, a source/drain stressor material 36 is epitaxially grown in the recess openings 28 (FIG. 4), thereby epitaxially forming a stressor layer over the etch stop layer. The thickness of the epitaxially grown stressor material 36 is determined according to the requirements of a desired semiconductor device application. For example, stressor material 36 can have a thickness on the order of 200-1000 angstroms. In addition, stressor material 36 includes a material for providing a compressive stress, or a tensile stress, according to the requirements of a desired semiconductor device application. Examples of stressor materials can include silicon, silicon germanium, silicon carbon, silicon germanium carbon, or other suitable stressor materials. In addition, in one embodiment, the stressor material 36 and the semiconductor layer 16 are not a same material. In one embodiment, stressor material 36 forms raised source/drain regions. Accordingly, the stressor layer thickness and strain can be well controlled.

In an alternate embodiment, the structure shown in FIG. 2 can be formed, starting with semiconductor substrate 12 and forming shallow trench isolation regions 18 in desired locations. The semiconductor substrate 12 that is between a pair of shallow trench isolation regions 18 can then be etched to a desired depth no greater than the depth of the shallow trench isolation regions, followed by an epitaxial growth of an etch stop layer 14. Following the formation of etch stop layer 14, a semiconductor layer 16 can be epitaxially grown, thereby achieving the structure of FIG. 2.

In another embodiment, the etch process of FIG. 4 includes an isotropic etch. With an isotropic etch, in addition to being bounded by the shallow trench isolation regions 18 and the underlying etch stop layer 14, the recess openings 28 would also include laterally etching further a portion of (or portions of) semiconductor layer 16 (FIG. 3) underlying the gate structure 20. The laterally etched portions are illustrated, for example, by the directional arrows 32 and lateral etch fronts 34 (shown in dashed lines on FIG. 4). The degree of the lateral etching is determined according to requirements of a desired semiconductor device application. Moreover, the remaining portion of semiconductor layer 16 (FIG. 3) is indicated by reference numeral 17 in FIG. 4. In one embodiment, the remaining portion 17 becomes a channel region of semiconductor device 10.

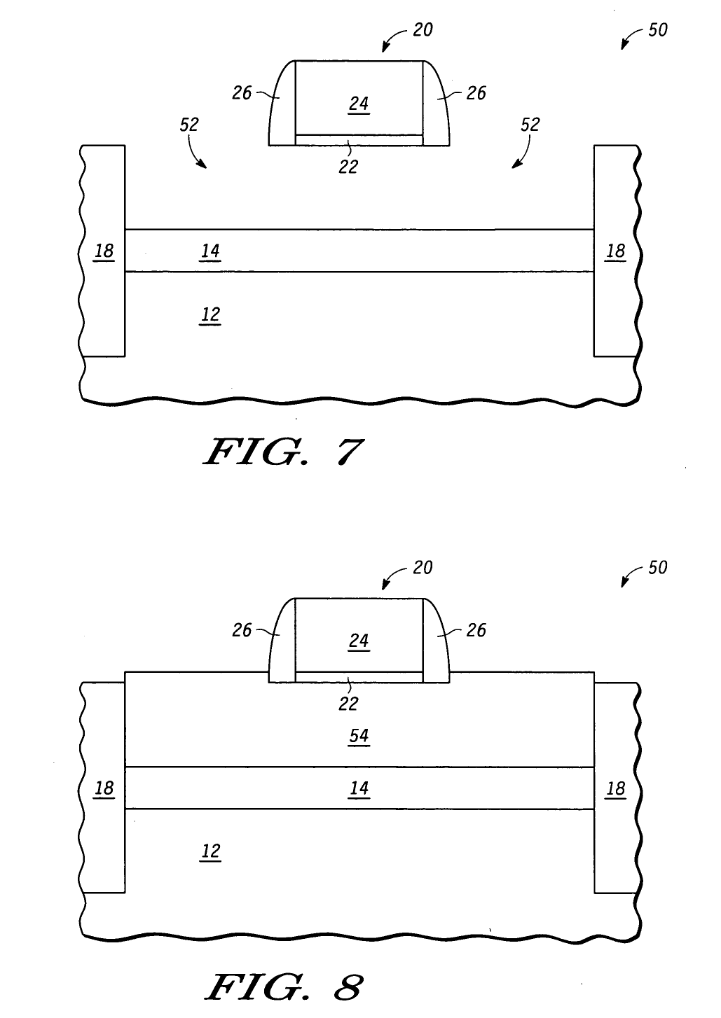

FIG. 6 is a cross-sectional drawing view of an exemplary transistor fabricated according to an embodiment of the present disclosure. Semiconductor device 10 includes gate structure 20, as discussed herein above. In one embodiment, gate electrode 24 is a control electrode. Semiconductor device 10 further includes source/drain extension regions 38 and source/drain regions 40. Furthermore, semiconductor device 10 includes silicided contacts 42 on the gate electrode 24 and source/drain regions 40. Source/drain extension regions 38, source/drain regions 40, and silicided contacts 42 are formed using conventional techniques. The source/drain extension regions can be formed before or after the source/drain etch recessing process. The source/drain regions can be formed during or after the selective epitaxial growth process for creating region 36. Additional gate spacers can be formed prior to source/drain formation. Furthermore, dopants for source/drain/extension regions can be incorporated through either implantation or in-situ doping during epitaxy.

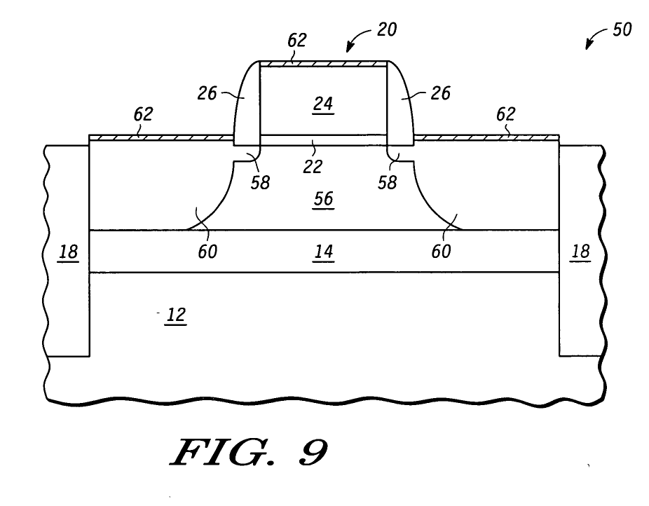

FIGS. 7-8 show a series of partial cross-sectional views of a stressed semiconductor device 50 at various stages during manufacture of an integrated circuit according to another embodiment of the present disclosure. The embodiment of FIGS. 7 and 8 are similar to the embodiments discussed herein above, with the following difference(s). In particular, layer 16 (FIG. 3) includes a removable layer, wherein the removable layer comprises any suitable layer that can be selectively removed with respect to the underlying etch stop layer 14, further as discussed below. In FIG. 7, following formation of the gate structure 20, semiconductor device 50 is subjected to an etch process. In one embodiment, the etch process includes an isotropic etch. The isotropic etch removes substantially all the semiconductor layer 16, including the portions covered and not covered by gate structure 20, thereby forming recess opening 52. The recess opening 52 is bounded by the shallow trench isolation regions 18 and also bounded by the etch stop layer 14 underlying semiconductor layer 16 (FIG. 3).

In FIG. 8, a source/drain and channel stressor material 54 is epitaxially grown in the recess opening 52 (FIG. 7). In one embodiment, the source/drain and channel stressor material substantially completely fills the recess opening 52, including underneath the region of gate structure 20. The thickness of the epitaxially grown stressor material 54 outside the region of gate structure 20 is determined according to the requirements of a desired semiconductor device application. In addition, stressor material 54 includes a material for providing a compressive stress, or a tensile stress, according to the requirements of a desired semiconductor device application. Examples of stressor materials can include silicon, silicon germanium, silicon carbon, silicon germanium carbon, or other suitable stressor materials. In one embodiment, stressor material 54 forms raised source/drain regions.

FIG. 9 is a cross-sectional drawing view of an exemplary transistor fabricated according to another embodiment of the present disclosure. Semiconductor device 50 includes gate structure 20, as discussed herein above. In one embodiment, gate electrode 24 is a control electrode. Semiconductor device 50 further includes strained channel region 56, source/drain extension regions 58 and source/drain regions 60. Furthermore, semiconductor device 50 includes silicided contacts 62 on the gate electrode 24 and source/drain regions 60. Source/drain extension regions 58, source/drain regions 60, and silicided contacts 62 are formed using conventional techniques. The source/drain extension region can be formed after the epitaxial growth of the stressor material 54 of FIG. 8. The source/drain region can be formed during or after the selective epitaxial growth of the stressor material. Additional gate spacers can be created prior to source/drain formation. Furthermore, dopants for source/drain/extension regions can be incorporated through either implantation or in-situ doping during epitaxy.

In one embodiment, the substrate has a natural state lattice constant in a lateral direction and the etch stop layer has a stressed lattice constant in the lateral direction. Accordingly, the stressed state lattice constant in the lateral direction of the etch stop layer is approximately equal to the natural state lattice constant in a lateral direction of the substrate.

In another embodiment, a stressor layer is formed over the etch stop layer, wherein the substrate has a natural state lattice constant in a lateral direction, the etch stop layer has a stressed state lattice constant in the lateral direction, and the stressor layer has a stressed state lattice constant in the lateral direction. Accordingly, the stressed state lattice constant in the lateral direction of the stressor layer is approximately equal to the stressed state lattice constant in the lateral direction of the etch stop layer and is approximately equal to the natural state lattice constant in a lateral direction of the substrate.

According to another embodiment, a portion of a semiconductor device includes a substrate; an etch stop layer epitaxially grown over at least a portion of the substrate; and a stressor layer epitaxially grown over at least a portion of the etch stop layer, wherein the stressor layer is under one of tensile and compressive stress. In another embodiment, a removable layer is formed over the etch stop layer, wherein the removable layer is selectively etchable with regard to the etch stop layer, wherein a portion of the removable layer is removed or substantially all of the removable layer is removed.

The portion of the semiconductor device further includes a gate structure formed over a region of the removable layer, wherein the region is not all of the removable layer, and wherein at least a portion of a source region and at least a portion of a drain region is formed in the stressor layer. In another embodiment, the portion of the semiconductor device further includes at least a portion of a channel region that is formed in the stressor layer.

The etch stop layer can include one or more of silicon germanium, silicon carbon, and silicon germanium carbon, wherein the etch stop layer has a thickness in a range of 50 angstroms to 300 angstroms. The stressor layer can include one or more of silicon, silicon germanium, silicon carbon and silicon germanium carbon.

In the foregoing specification, the disclosure has been described with reference to various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments. For example, the present embodiments can apply to semiconductor device technologies where carrier mobility is crucial to the device performance.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for forming at least a portion of a semiconductor device, comprising:
providing a substrate;
epitaxially forming an etch stop layer over the substrate;
providing a first layer over the etch stop layer, wherein the first layer is selectively etchable with regard to the etch stop layer;
providing a structure over a region of the first layer, wherein the region is not all of the first layer; and
etching at least a portion of the first layer that is outside of the region, wherein the etch stop layer is used as an etch stop.

2. A method as in claim 1, wherein the etch stop layer includes one selected from a group of silicon germanium, silicon carbon, and silicon germanium carbon.

3. A method as in claim 1, wherein the etch stop layer has a thickness in a range of 50 Angstroms to 300 Angstroms.

4. A method as in claim 1, wherein after etching, the top surface of the etch stop layer comprises a substantially planar surface.

5. A method as in claim 1, further comprising:
epitaxially forming a stressor layer over the etch stop layer.

6. A method as in claim 5, wherein the stressor layer has a thickness in a range of 200 Angstroms to 1000 Angstroms.

7. A method as in claim 5, wherein the first layer includes one selected from a group of silicon, silicon germanium, silicon carbon and silicon germanium carbon, and wherein the first layer and the stressor layer are not a same material.

8. A method as in claim 5, wherein the stressor layer is under compressive stress.

9. A method as in claim 5, wherein the stressor layer is under tensile stress.

10. A method as in claim 1, wherein the stressor layer includes one selected from a group of silicon, silicon germanium, silicon carbon and silicon germanium carbon.

11. A method as in claim 1, further comprising:
etching a portion of the first layer that is within the region.

12. A method as in claim 1, further comprising:
etching substantially all of the first layer that is within the region.

13. A method as in claim 1, wherein the first layer comprises a semiconductor material.

14. A method as in claim 1, wherein the structure is a gate structure.

15. A method as in claim 1, wherein the semiconductor device comprises a transistor.

16. A method as in claim 1, wherein the substrate has a natural state lattice constant in a lateral direction, the etch stop layer has a stressed lattice constant in the lateral direction, and wherein the stressed state lattice constant in the lateral direction of the etch stop layer is approximately equal to the natural state lattice constant in a lateral direction of the substrate.

17. A method as in claim 1, further comprising:
forming a stressor layer over the etch stop layer,
wherein the substrate has a natural state lattice constant in a lateral direction, the etch stop layer has a stressed state lattice constant in the lateral direction, and the stressor layer has a stressed state lattice constant in the lateral direction, and wherein the stressed state lattice constant in the lateral direction of the stressor layer is approximately equal to the stressed state lattice constant in the lateral direction of the etch stop layer and is approximately equal to the natural state lattice constant in a lateral direction of the substrate.

18. A method for forming a portion of a semiconductor device, comprising:
epitaxially forming an etch stop layer.

19. A method as in claim 18, wherein the etch stop layer includes one selected from a group of silicon germanium, silicon carbon, and silicon germanium carbon.

20. A portion of a semiconductor device, comprising:
a substrate;
an etch stop layer epitaxially grown over at least a portion of the substrate; and
a stressor layer epitaxially grown over at least a portion of the etch stop layer, wherein the stressor layer is under one of tensile and compressive stress.

21. A portion of a semiconductor device as in claim 20, comprising:
a removable layer formed over the etch stop layer, wherein the removable layer is selectively etchable with regard to the etch stop layer.

22. A portion of a semiconductor device as in claim 21, wherein a portion of the removable layer is removed.

23. A portion of a semiconductor device as in claim 21, wherein substantially all of the removable layer is removed.

24. A portion of a semiconductor device as in claim 20, further comprising:
a gate structure formed over a region of the removable layer, wherein the region is not all of the removable layer, and
wherein at least a portion of a source region and at least a portion of a drain region is formed in the stressor layer.

25. A portion of a semiconductor device as in claim 24, wherein at least a portion of a channel region is formed in the stressor layer.

26. A portion of a semiconductor device as in claim 20, wherein the etch stop layer includes one selected from a group of silicon germanium, silicon carbon, and silicon germanium carbon.

27. A portion of a semiconductor device as in claim 20, wherein the stressor layer includes one selected from a group of silicon, silicon germanium, silicon carbon and silicon germanium carbon.

28. A method as in claim 20, wherein the etch stop layer has a thickness in a range of 50 Angstroms to 300 Angstroms.

29. A portion of a semiconductor device, comprising:
an etch stop layer, wherein the etch stop layer comprises at least one material selected from a group of silicon germanium, silicon carbon, and silicon germanium carbon.
